(19) United States
(12) Patent Application Publication
(10) Pub. No.: US 2012/0174392 A1
(43) Pub. Date: Jul. 12, 2012

(54) Method of fabricating printed circuit board

(76) Inventors: Ron Shih, Taipei (TW); Tong Miin Liou, Taipei (TW); Kuan Cheng Shih, Taipei (TW); Chia Yen Chan, (US)

(21) Appl. No.: 12/930,428

(22) Filed: Jan. 6, 2011

(51) Int. Cl. H05K 3/10

(52) U.S. Cl. 29/846

(57) ABSTRACT

A method for manufacturing a printed circuit board includes applying a layer of an ink material onto the substrate, the ink material includes a number of conductive particles contained in a solution, and the substrate is then heated to remove the solution and to sinter or retain the conductive particles on the substrate and to form a conductive metal line on the substrate of the printed circuit board. One or more additional layers of the ink material are applied onto the conductive metal line of the substrate with an electroplating process, or by repeating applying the ink material onto the conductive metal line and heating and retaining the conductive particles on the conductive metal line of the substrate.

### BACKGROUND OF THE INVENTION

1. Field of the Invention

The present invention relates to a printed circuit board fabricating or manufacturing method, and more particularly to a method of fabricating or manufacturing a printed circuit board including a simplified fabricating or manufacturing procedure for decreasing the fabricating or manufacturing cost and for reducing the required fabricating or manufacturing facilities or machines and for fabricating or manufacturing the high quality printed circuit board.

2. Description of the Prior Art

Various kinds of typical printed circuit boards (PCBs) or printed wiring boards (PWBs) have been developed and comprise rigid PCBs or flexible PCBs, and may also comprise single sided PCBs, double sided PCBs, or multilayer PCBs.

For example, U.S. Pat. No. 4,935,584 to Boggs, and U.S. Pat. No. 6,902,660 to Lee et al. disclose two of the typical methods of fabricating or manufacturing printed circuit boards and the printed circuit boards produced, and comprising one or more base substrates to be plated or adhered with at least one conductive run or a metal on a pattern-formed metallic substrate to form a conductive metal line.

However, a number of plating or adhering processes, hole forming processes, electroplating processes, drying processes, exposing processes, etching processes, or other complicated processes are required to fabricate or manufacture the printed circuit boards such that the required fabricating or manufacturing facilities or machines are great and the fabricating or manufacturing cost for fabricating or manufacturing the printed circuit boards will be greatly increased.

The present invention has arisen to mitigate and/or obviate the afore-described disadvantages of the conventional methods of manufacturing printed circuit boards.

### SUMMARY OF THE INVENTION

The primary objective of the present invention is to provide a method of manufacturing printed circuit board including a simplified fabricating or manufacturing procedure or process for decreasing the fabricating or manufacturing cost and for reducing the required fabricating or manufacturing facilities or machines and for fabricating or manufacturing the high quality printed circuit board.

In accordance with one aspect of the invention, there is provided a method for manufacturing a printed circuit board comprising preparing a substrate, applying a layer of an ink material onto the substrate, the ink material including a plurality of conductive particles contained in a solution, and heating the substrate and the ink material to remove the solution and to retain the conductive particles on the substrate and to form a conductive metal line on the substrate, and to form the conductive metal line on the printed circuit board.

The conductive particles may be selected from silver particles, such as the nanomized silver particles, the nanomized conductive particles, or the like.

An electroplating process may further be provided to apply at least one second layer of the ink material onto the conductive metal line of the substrate and to increase the thickness of the conductive metal line.

An applying process may further be provided to apply at least one second layer of the ink material onto the conductive metal line of the substrate, and heating the substrate and the second layer of the ink material to remove the solution and to retain the conductive particles on the conductive metal line of the substrate and to form at least one second layer of the conductive metal line on the conductive metal line of the substrate, and to form the printed circuit board.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a side plan schematic view of a printed circuit board to be fabricated or manufactured with a fabricating or manufacturing method in accordance with the present invention;

FIG. 2 is an enlarged side plan schematic view of the fabricated or manufactured printed circuit board;

FIG. 3 is a block diagram illustrating the processes or procedures for conducting or operating the fabricating or manufacturing method in accordance with the present invention; and

FIG. 4 is another block diagram similar to FIG. 3, illustrating the other processes or procedures for fabricating or manufacturing the printed circuit boards.

### DETAILED DESCRIPTION OF THE PREFERRED EMBODIMENT

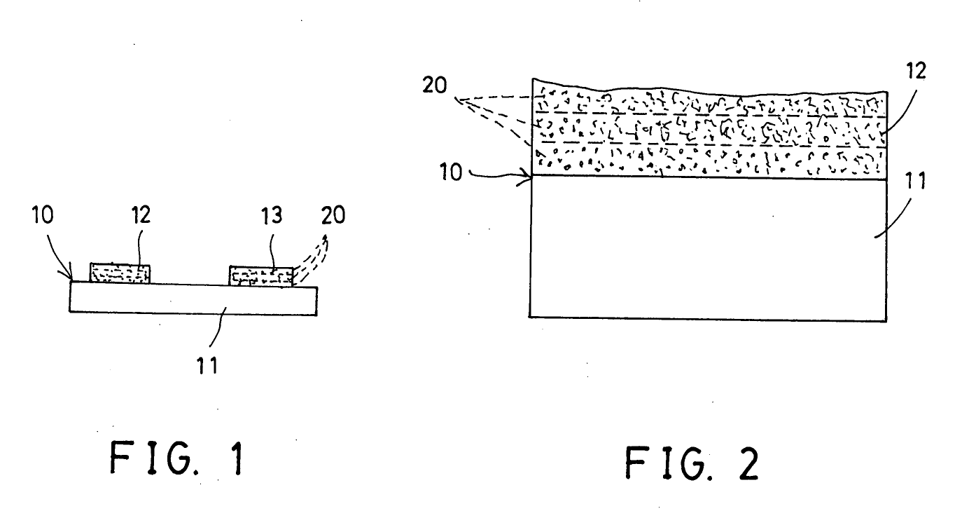

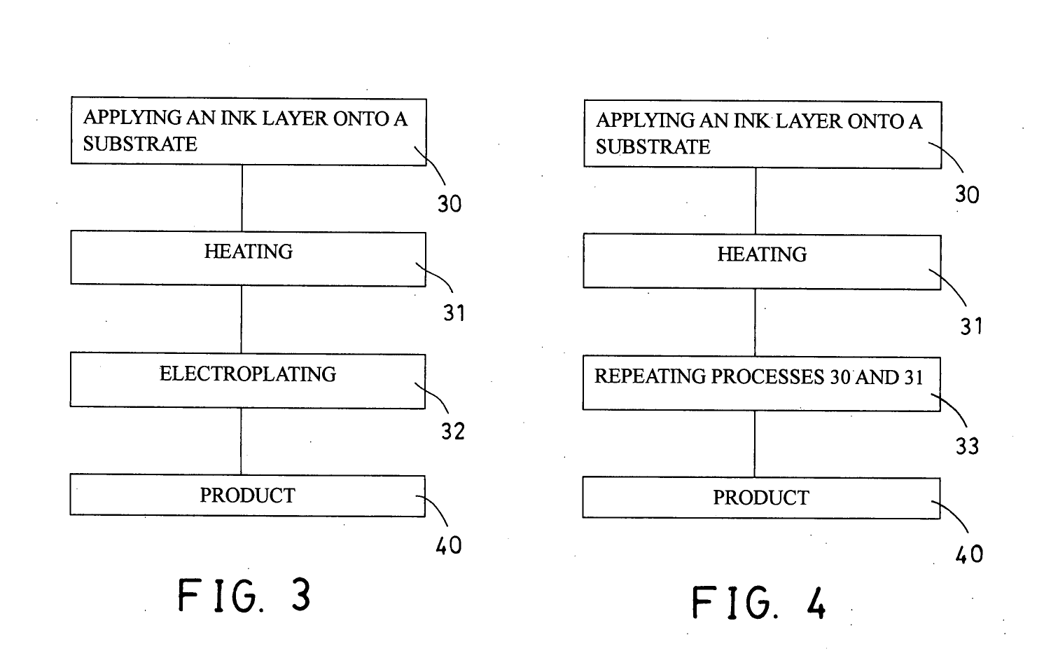

Referring to the drawings, and initially to FIGS. 1 and 2, a method in accordance with the present invention is provided for fabricating or manufacturing the printed circuit board 10 which comprises preparing a substrate 11 which includes one or more conductive metal lines 12, 13 applied or printed or formed thereon, and the method further comprises printing or applying or painting one or more ink materials or layers 20 onto the substrate 11 with an inkjet printing facility or machine (not shown), such as a thermal bubble type inkjet printing machine, a piezoelectric type inkjet printing machine, or the like for forming the conductive metal lines 12, 13, in the process or procedure 30 (FIG. 3).

The ink material or layer 20 includes a number of nanomized silver particles or nanomized conductive particles or the like contained or mixed within a solution, and will be printed or applied or painted onto the substrate 11 with the inkjet printing facilities or machines for forming the conductive metal lines 12, 13 on the substrate 11. As disclosed in FIG. 3, the substrate 11 with the printed or applied or painted ink materials or layers 20 or conductive metal lines 12, 13 will then be disposed in or engaged into an oven (not shown) for heating the substrate 11 and the ink materials or layers 20 and for drying or evaporating or removing the solution contained in the ink materials or layers 20, in the process or procedure 31.

After the heating or drying or evaporating or removing process or procedure, the conductive or silver particles will be heated or sintered or secured or retained on the substrate 11 to form the conductive metal lines 12, 13 on the substrate 11. The heating process or procedure may be conducted or operated with different heating temperatures, such as 100° C., 150° C., 200° C., 250° C., etc. For example, when the substrate 11 and the ink materials or layers 20 are heated with a temperature of 100° C., boundary lines or surfaces may be formed between or among the conductive or silver particles, or the conductive or silver particles may not be suitably melted and secured together, and the resistance of the conductive or silver particles is measured to be about 840 Ωs. It is preferable that the substrate 11 is made of poly ethylene terephthalate (PET) or the like.

When the substrate 11 and the ink materials or layers 20 are heated with an increased temperature of about 150° C., the conductive or silver particles may be slightly melted and secured together and the boundary lines or surfaces between or among the conductive or silver particles may be slightly decreased or removed, and the resistance of the conductive or silver particles will be slightly decreased or less than 840 Ωs. It is also preferable that the substrate 11 is made of poly ethylene terephthalate (PET) or the like. When the substrate 11 is made of poly iso butylene (PI) or the like, and when the substrate 11 and the ink materials or layers 20 are heated with a further increased temperature of about 200° C., the conductive or silver particles may be suitably melted and secured together and the boundary lines or surfaces between or among the conductive or silver particles may further be decreased or removed, and the resistance of the conductive or silver particles will be suitably decreased to about 490 Ωs.

When the substrate 11 is also made of poly iso butylene (PI) or the like, and when the substrate 11 and the ink materials or layers 20 are heated with a still further increased temperature of about 250° C., the conductive or silver particles may be suitably or completely melted and secured together and the boundary lines or surfaces between or among the conductive or silver particles may further be decreased or removed, and the resistance of the conductive or silver particles will be suitably decreased to about 350 Ωs. The substrate 11 and the ink materials or layers 20 may be heated with any suitable or selected heating temperature to have the conductive or silver particles slightly or suitable or completely melted and secured together, and/or to have the boundary lines or surfaces between or among the conductive or silver particles to be slightly or suitable or completely decreased or removed, and to have the resistance at the required or selected values.

After the heating process or procedure, the substrate 11 with the heated or sintered conductive or silver particles will then be conducted or operated with an electroplating process or procedure 32 to apply much more layers of the conductive or silver particles or conductive metal lines 12, 13 onto the heated or sintered conductive or silver particles or onto the previously formed conductive metal lines 12, 13, and to increase the thickness of the ink materials or layers 20 or the conductive metal lines 12, 13, and to form the final product 40, and to further decrease the resistance of the ink materials or layers 20 or the conductive metal lines 12, 13; i.e., the resistance (R) will be decreased when the area (A) is increased, that is obtained from the following equation: R=L (length) times ρ (coefficient or resistance)/A (area).

Alternatively, as shown in FIG. 4, other than the electroplating process or procedure 32 as that shown in FIG. 3, the thickness of the ink materials or layers 20 or the conductive metal lines 12, 13 may also be suitably increased by repeating the printing or applying or painting process or procedure 30 and the heating process or procedure 31 in the process or procedure 33, in order to apply much more layers of the ink materials or layers 20 or the conductive metal lines 12, 13 onto the previously applied or formed ink materials or layers 20 or the conductive metal lines 12, 13 and to suitably increase the ink materials or layers 20 or the conductive metal lines 12, 13 to the required or selected value or thickness.

Accordingly, the method of manufacturing printed circuit board in accordance with the present invention includes a simplified fabricating or manufacturing procedure for decreasing the fabricating or manufacturing cost and for reducing the required fabricating or manufacturing facilities or machines and for fabricating or manufacturing or obtaining the high quality printed circuit board.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A method for manufacturing a printed circuit board comprising:
preparing a substrate,
applying a layer of an ink material onto said substrate, said ink material including a plurality of conductive particles contained in a solution, and
heating said substrate and said ink material to remove the solution and to retain said conductive particles on said substrate and to form a conductive metal line on said substrate, and to form said printed circuit board.

2. The method of manufacturing printed circuit board as claimed in claim 1, wherein said conductive particles are selected from silver particles.

3. The method of manufacturing printed circuit board as claimed in claim 2, wherein said silver particles are selected from nanomized silver particles.

4. The method of manufacturing printed circuit board as claimed in claim 1, wherein said conductive particles are selected from nanomized conductive particles.

5. The method of manufacturing printed circuit board as claimed in claim 1 further comprising electroplating at least one second layer of the ink material onto said conductive metal line of said substrate.

6. The method of manufacturing printed circuit board as claimed in claim 1 further comprising applying at least one second layer of the ink material onto said conductive metal line of said substrate, and heating said substrate and said at least one second layer of the ink material to remove the solution and to retain said conductive particles on said conductive metal line of said substrate and to form at least one second layer of said conductive metal line on said conductive metal line of said substrate, and to form said printed circuit board.
